(19) United States
(12) Patent Application Publication
(10) Pub. No.: US 2025/0342288 A1
(43) Pub. Date: Nov. 6, 2025

(54) HAPTIC SIMULATION SYSTEM FOR A VEHICLE DOOR

(71) Applicants: HYUNDAI MOTOR COMPANY, Seoul (KR); KIA CORPORATION, Seoul (KR); KOREA ADVANCED INSTITUTE OF SCIENCE AND TECHNOLOGY, Daejeon (KR)

(72) Inventors: Jae Hoon Chung, Hwaseong-si (KR); Ki Uk Kyung, Daejeon (KR); Ji Hyeong Ma, Daejeon (KR); Ji Sung Kim, Daejeon (KR)

(73) Assignees: HYUNDAI MOTOR COMPANY, Seoul (KR); KIA CORPORATION, Seoul (KR); KOREA ADVANCED INSTITUTE OF SCIENCE AND TECHNOLOGY, Daejeon (KR)

(21) Appl. No.: 18/928,644

(22) Filed: Oct. 28, 2024

(30) Foreign Application Priority Data
May 2, 2024 (KR) 10-2024-0058630

(51) Int. Cl. G06F 30/20; G06F 30/15

(52) U.S. Cl. CPC G06F 30/20; G06F 30/15

(57) ABSTRACT

A haptic simulation system for a vehicle door includes a haptic simulator having a simulator frame, a simulator door rotatably connected to the simulator frame through a shaft, a motor configured to rotate the shaft, and a brake configured to brake the shaft. The motor provides an active torque to the shaft and the brake provides a passive torque to the shaft.

### CROSS-REFERENCE TO RELATED APPLICATION

This application is based on and claims the benefit of priority to Korean Patent Application No. 10-2024-0058630, filed on May 2, 2024 in the Korean Intellectual Property Office, the disclosure of which is incorporated herein in its entirety by reference.

### TECHNICAL FIELD

The present disclosure relates to a haptic simulation system for a vehicle door, and more particularly, to a haptic simulation system for a vehicle door configured to realistically simulate the sense of opening and closing, manipulation, and the like of a virtual vehicle door to be designed.

### BACKGROUND

In a process of designing a vehicle door, various information such as the weight of the door, the center of gravity of the door, and the torque profile of a checker assembly may be checked. However, it may be difficult to know what kind of feeling, i.e., tactile feedback, the vehicle door provides to a user when all of the various information checked in the design process are combined. Accordingly, in order to feel the sense of opening and closing of the vehicle door, a physical prototype should be made and tested. However, prototype production may be very inefficient due to high cost and long production time.

Virtual prototype technology refers to testing in a virtual environment without producing a prototype in a product development process. Most of the virtual prototype technologies in the field of haptics use commercial haptic simulators, such as PHANTOM premium, PHANTOM Omni, and Omega series of Force Dimension. However, since these commercial haptic simulators have small operating ranges and simulate small physical forces, they may not be used in cases in which large physical forces and large operating ranges are required (e.g., vehicle door simulation).

Since the existing commercial haptic simulators have limits in providing large operating ranges and simulating large physical forces, there have been some development cases of haptic simulators for specific applications.

For example, a haptic simulator that simulates the sense of opening and closing of a vehicle door was developed at the Technical University of Munich in Germany in 2011 (see Strolz, Michael, et al. “Development and evaluation of a device for the haptic rendering of rotatory car doors” IEEE Transactions on Industrial Electronics 58.8 (2010): 3133-3140). Such a haptic simulator was configured to provide haptic feedback using a motor with a relatively high output torque (100 Nm) to simulate the opening and closing torque of the vehicle door. Since this haptic simulator used the motor with high output torque, there was a risk that a user could suffer serious injury if the user was hit by or caught in the simulator door. To minimize this risk, a limited control method was used and the vibration of the large motor itself made the user aware of different physical sensations (a sense of difference). In addition, since a force sensor measuring a force between the user and the simulator was mounted on a handle, the user could not perform the haptic simulation while holding any part of the simulator other than the handle.

In addition, a haptic simulator that simulates the sense of opening and closing of a refrigerator door was developed at Pohang University of Science and Technology in Korea in 2012 (see Shin, Sunghwan, et al. “Haptic simulation of refrigerator door” 2012 IEEE Haptics Symposium (HAPTICS). IEEE, 2012). Such a haptic simulator only used a motor, so there was a risk of injury to a user. In addition, since this haptic simulator did not include a torque/force sensor, it performed open-loop control without feedback, limiting realistic haptic simulation.

As described above, the existing haptic simulators are haptic devices that only use the motor. In a case in which the torque profile (for example, a torque profile that changes the direction of the torque when the vehicle door is opened and closed) is different depending on the opening and closing of the vehicle door, the rotation direction (the direction of the torque provided) of the motor changes drastically as the simulator door is opened and closed. Due to this drastic change in the rotation direction (torque direction), the user may feel the sense of difference, and the risk of errors occurring in the control of the haptic simulator may increase.

The above information described in this background section is provided to assist in understanding the background of the inventive concept. Thus, the background section may include technical concepts that are not considered as the prior art that is already known to those of ordinary skill in the art.

### SUMMARY

The present disclosure has been made to solve the above-mentioned problems occurring in the prior art while advantages achieved by the prior art are maintained intact.

An aspect of the present disclosure provides a haptic simulation system for a vehicle door configured to realistically simulate the sense of opening and closing, manipulation, and the like of a virtual vehicle door to be designed without a prototype.

According to an aspect of the present disclosure, a haptic simulation system for a vehicle door may include: a haptic simulator including a simulator frame, a simulator door rotatably connected to the simulator frame through a shaft, a motor configured to rotate the shaft, and a brake configured to brake the shaft. The motor may provide an active torque to the shaft and the brake may provide a passive torque to the shaft.

The active torque may be a torque in a direction that does not change regardless of the opening and closing of the vehicle door. The passive torque may be a torque in a direction that changes depending on the opening and closing of the vehicle door.

The haptic simulator may further include a torque sensor configured to measure a torque of the shaft.

The simulator frame may include at least two stoppers limiting a rotation angle of the simulator door.

The haptic simulator may further include a connection mechanism configured to connect the simulator door to the shaft. The connection mechanism may be configured to adjust a height of the simulator door.

The haptic simulator may further include a simulator handle mounted on the simulator door.

The haptic simulator may further include an adjustment unit configured to adjust a height of the simulator handle with respect to the simulator door.

The haptic simulation system may further include an input/output mechanism configured to receive information on a virtual vehicle door to be designed and to output a haptic simulation state of the haptic simulator manipulated by a user.

The haptic simulation system may further include a controller. The controller may be configured to transmit a control signal to the haptic simulator. The control signal may be generated based on the information on the virtual vehicle door input to the input/output mechanism and the haptic simulation state of the haptic simulator manipulated by the user to the haptic simulator. The controller may also be configured to transmit the haptic simulation state of the haptic simulator to the input/output mechanism.

The controller may include a door model configured to calculate a physical force, which the virtual vehicle door applies to the user, based on the information on the virtual vehicle door input to the input/output mechanism and the haptic simulation state of the haptic simulator. The controller may also include a torque distributor configured to convert the physical force calculated by the door model into an electric signal.

The door model may be configured to distribute the physical force into an active torque and a passive torque and to transmit the torques to the torque distributor.

The torque distributor may be configured to convert the active torque into an electric signal of the motor and to convert the passive torque into an electric signal of the brake.

### BRIEF DESCRIPTION OF THE DRAWINGS

The above and other objects, features, and advantages of the present disclosure should be more apparent from the following detailed description taken in conjunction with the accompanying drawings, in which:

FIG. 1 illustrates a schematic view of a haptic simulation system for a vehicle door according to an embodiment of the present disclosure;

FIG. 2 illustrates a haptic simulator in a haptic simulation system for a vehicle door according to an embodiment of the present disclosure;

FIG. 3 illustrates the connection relationship of a simulator door, a shaft, a connection mechanism, a torque sensor, a motor, and a brake in the haptic simulator illustrated in FIG. 2;

FIG. 4 illustrates a simulator handle and an adjustment unit in the haptic simulator illustrated in FIG. 2;

FIG. 5 illustrates a block diagram of a haptic simulation system for a vehicle door according to an embodiment of the present disclosure;

FIG. 6 illustrates a diagram of a controller of the haptic simulation system illustrated in FIG. 5;

FIG. 7 illustrates a graph of an opening torque generated by a checker assembly of a vehicle door;

FIG. 8 illustrates a graph of a closing torque generated by a checker assembly of a vehicle door;

FIG. 9 illustrates an active torque and a passive torque acting on a vehicle door when the vehicle door is opened;

FIG. 10 illustrates an active torque and a passive torque acting on a vehicle door when the vehicle door is closed; and

FIG. 11 illustrates a flowchart of a process of controlling a haptic simulation system for a vehicle door according to an embodiment of the present disclosure.

### DETAILED DESCRIPTION

Hereinafter, embodiments of the present disclosure are described in detail with reference to the accompanying drawings. In the drawings, the same reference numerals are used throughout to designate the same or equivalent elements. In addition, a detailed description of well-known techniques associated with the present disclosure have been omitted in order not to unnecessarily obscure the gist of the present disclosure.

Terms such as first, second, A, B, (a), and (b) may be used to describe the elements in embodiments of the present disclosure. These terms are only used to distinguish one element from another element, and the intrinsic features, sequence or order, and the like of the corresponding elements are not limited by the terms. Unless otherwise defined, all terms used herein, including technical or scientific terms, have the same meanings as those generally understood by those with ordinary knowledge in the field of art to which the present disclosure belongs. Such terms as those defined in a generally used dictionary are to be interpreted as having meanings consistent with the contextual meanings in the relevant field of art. Such terms are not to be interpreted as having ideal or excessively formal meanings unless clearly defined as having such in the present application.

When a controller, module, component, device, element, or the like of the present disclosure is described as having a purpose or performing an operation, function, or the like, the controller, module, component, device, element, or the like should be considered herein as being “configured to” meet that purpose or to perform that operation or function. Each controller, module, component, device, element, and the like may separately embody or be included with a processor and a memory, such as a non-transitory computer readable media, as part of the apparatus.

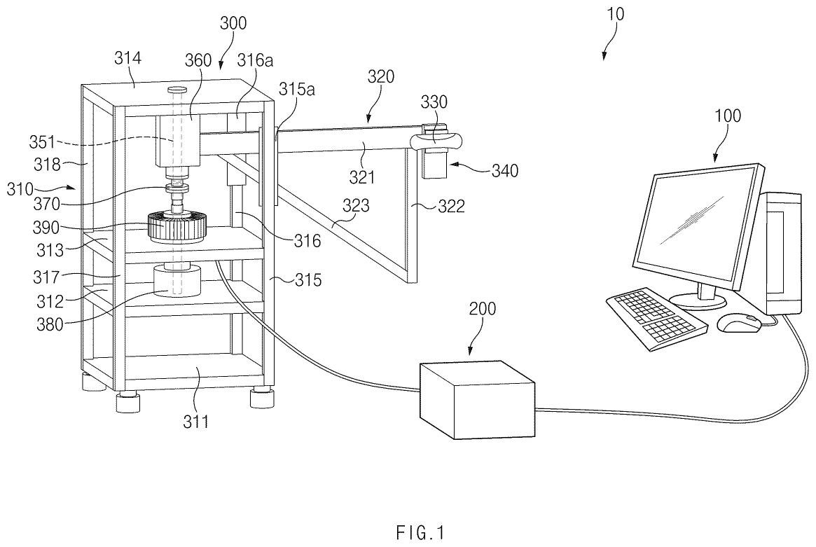

Referring to FIG. 1, a haptic simulation system 10 for a vehicle door according to an embodiment of the present disclosure may include an input/output mechanism 100, a controller 200 operably connected to the input/output mechanism 100, and a haptic simulator 300 operably connected to the controller 200.

The input/output mechanism 100 may be configured to receive information on a virtual vehicle door to be designed from a user and to output a haptic simulation state of the haptic simulator 300 manipulated by the user.

The controller 200 may be configured to transmit a control signal generated based on the information on the virtual vehicle door input to the input/output mechanism 100 and the haptic simulation state of the haptic simulator 300 manipulated by the user to the haptic simulator 300. The controller 200 may also be configured to transmit the haptic simulation state of the haptic simulator 300 to the input/output mechanism 100.

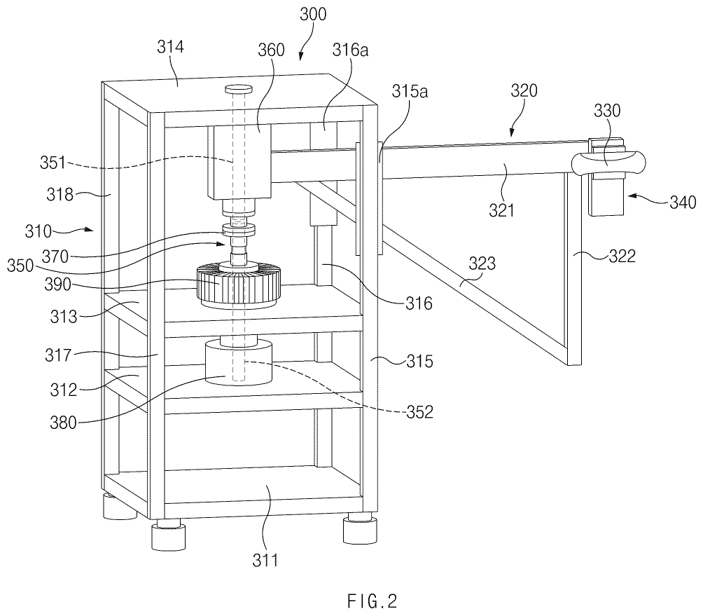

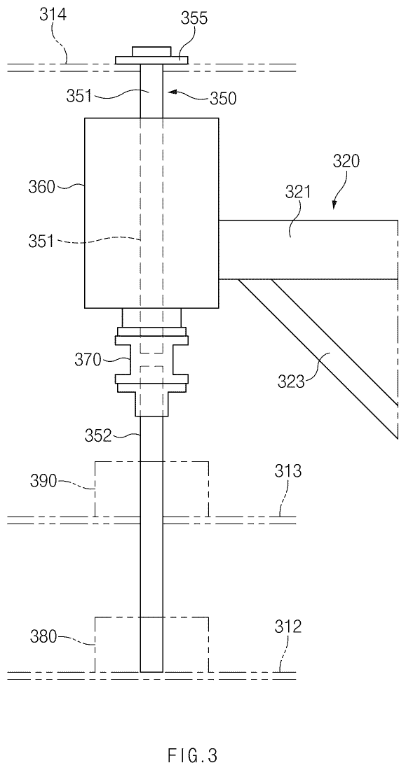

Referring to FIGS. 2 and 3, the haptic simulator 300 may include a simulator frame 310 and a simulator door 320 rotatably connected to the simulator frame 310 through a shaft 350.

The simulator frame 310 may include a base plate 311, a first support plate 312 located above the base plate 311, a second support plate 313 located above the first support plate 312, a top plate 314 located above the second support plate 313, and a plurality of vertical members 315, 316, 317, and 318 connecting the base plate 311, the first support plate 312, the second support plate 313, and the top plate 314.

The base plate 311 may be supported with respect to the ground through a plurality of wheels or supports. The first support plate 312 may be spaced apart upward from the base plate 311. The second support plate 313 may be spaced apart upward from the first support plate 312. The top plate 314 may be spaced apart upward from the second support plate 313.

The plurality of vertical members 315, 316, 317, and 318 may connect the base plate 311, the first support plate 312, the second support plate 313, and the top plate 314 in a vertical direction. The plurality of vertical members 315, 316, 317, and 318 may include a first vertical member 315 and a second vertical member 316 facing the simulator door 320, and a third vertical member 317 and a fourth vertical member 318 located far from the simulator door 320. At least two vertical members of the plurality of vertical members 315, 316, 317, and 318 may correspond to a pair of stoppers limiting a rotation angle of the simulator door 320. In other words, the first vertical member 315 and the second vertical member 316 may be the pair of stoppers limiting the rotation angle of the simulator door 320.

The shaft 350 may be rotatably mounted on the center of the simulator frame 310 and the shaft 350 may extend in a height direction (vertical direction) of the simulator frame 310. The shaft 350 may be rotatably supported to the simulator frame 310 through a bearing 355. Referring to FIG. 3, the bearing 355 may be mounted at a top end of the shaft 350. Accordingly, the top end of the shaft 350 may be rotatably supported on the center of the top plate 314 of the simulator frame 310 through the bearing 355.

Referring to FIG. 2, the simulator door 320 may include a first door member 321 rotatably connected to the simulator frame 310 through the shaft 350. The first door member 321 may extend horizontally from the center of the simulator frame 310 to the outside of the simulator frame 310. The simulator door 320 may include a second door member 322 vertically connected to the first door member 321 and may include a third door member 323 obliquely connecting the first door member 321 and the second door member 322.

Referring to FIG. 2, as the first door member 321 of the simulator door 320 rotates around the shaft 350, a rotation angle of the first door member 321 of the simulator door 320 may be defined by the first vertical member 315 and the second vertical member 316 corresponding to the stoppers. The first vertical member 315 may have a first shock-absorbing member 315a absorbing impact on the simulator door 320. When the simulator door 320 comes into contact with the first vertical member 315, the shock resulting from contact with the simulator door 320 may be reduced by the first shock-absorbing member 315a. The second vertical member 316 may have a second shock-absorbing member 316a absorbing impact on the simulator door 320. When the simulator door 320 comes into contact with the second vertical member 316, the shock resulting from contact with the simulator door 320 may be reduced by the second shock-absorbing member 316a.

Referring to FIGS. 2 and 3, the haptic simulator 300 may include a connection mechanism 360 connecting the simulator door 320 to the shaft 350. The connection mechanism 360 may be mounted on the shaft 350 and the connection mechanism 360 may be configured to adjust the height of the simulator door 320. For example, a first end portion of the first door member 321 of the simulator door 320 may be mounted on the connection mechanism 360 to move upwards and downwards. Accordingly, the height of the first end portion of the first door member 321 may be adjusted by the connection mechanism 360.

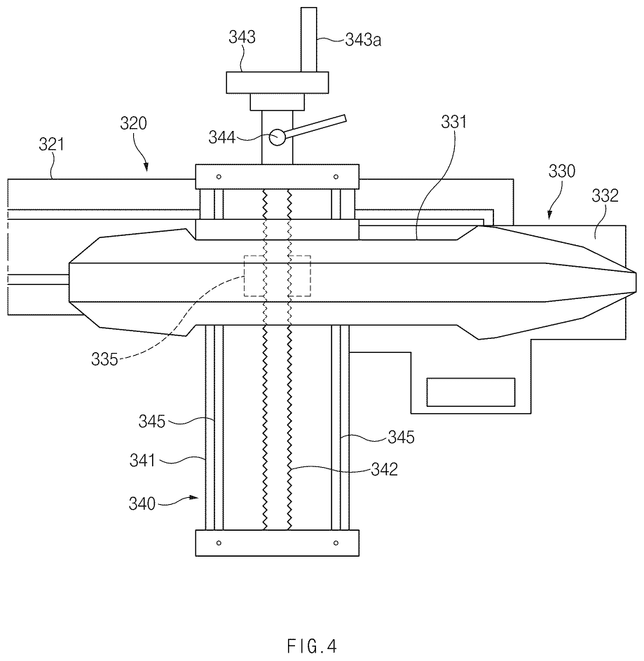

Referring to FIG. 2, the haptic simulator 300 may include a simulator handle 330 mounted on the simulator door 320. The simulator handle 330 may be connected to a second end portion of the first door member 321 of the simulator door 320. Referring to FIG. 4, the simulator handle 330 may include a handle grip 331 and a base panel 332 on which the handle grip 331 is mounted.

Referring to FIG. 2, the haptic simulator 300 may include an adjustment unit 340 configured to adjust the height of the simulator handle 330 with respect to the first door member 321 of the simulator door 320. The adjustment unit 340 may be mounted on the second end portion of the first door member 321. The simulator handle 330 may be connected to the first door member 321 of the simulator door 320 through the adjustment unit 340 to move in a vertical direction and a horizontal direction.

Referring to FIG. 4, the adjustment unit 340 may include a support block 341, a lead screw 342 rotatably mounted in the support block 341, a rotating plate 343 connected to a top end of the lead screw 342, a set screw 344 located below the rotating plate 343, and a pair of guide rods 345 disposed on both sides of the lead screw 342. The support block 341 may extend vertically from the second end portion of the first door member 321. The lead screw 342 may extend vertically and the lead screw 342 may be rotatably supported inside the support block 341. The rotating plate 343 may be fixed to the top end of the lead screw 342. The rotating plate 343 may have a grip 343a extending vertically from a top surface thereof. The set screw 344 may be releasably fixed to the lead screw 342. Each guide rod 345 may extend vertically and the guide rods 345 may be parallel to the lead screw 342.

The simulator handle 330 may have a lead nut 335 fixed to the base panel 332 and the lead nut 335 may mesh with the lead screw 342. As the lead screw 342 rotates, the base panel 332 and the lead nut 335 of the simulator handle 330 may move in a longitudinal direction of the lead screw 342.

The support block 341 may be configured to move in a longitudinal direction of the first door member 321. Accordingly, the simulator handle 330 may move in the longitudinal direction of the first door member 321 of the simulator door 320 through the support block 341.

Referring to FIGS. 1-3, the haptic simulator 300 may include a torque sensor 370 connected to the shaft 350. The torque sensor 370 may be configured to sense a torque of the shaft 350 in real time. The torque sensor 370 may be located below the connection mechanism 360.

Referring to FIG. 3, the shaft 350 may include a first portion 351 and a second portion 352 connected below the first portion 351. A bottom end of the first portion 351 may be fixed or connected to an upper portion of the torque sensor 370 and a top end of the second portion 352 may be fixed or connected to a lower portion of the torque sensor 370.

Referring to FIGS. 1-3, the haptic simulator 300 may include a motor 380 connected to the shaft 350. The motor 380 may be connected to a bottom end of the shaft 350. According to an embodiment, the motor 380 may be directly connected to the shaft 350. According to another embodiment, the motor 380 may be indirectly connected to the shaft 350 through a reducer to amplify the torque. The motor 380 may be configured to provide a driving torque corresponding to an active torque to the shaft 350 in one direction. Specifically, the motor 380 may rotate the shaft 350 in one direction and the motor 380 may be supported to the first support plate 312. For example, the motor 380 may be a servomotor capable of measuring the rotation angle, a DC motor having an encoder, or the like.

Referring to FIGS. 1-3, the haptic simulator 300 may include a brake 390 connected to the shaft 350. According to an embodiment, the brake 390 may be directly connected to the shaft 350. According to another embodiment, the brake 390 may be indirectly connected to the shaft 350 through a reducer to amplify the torque. The brake 390 may be configured to provide a braking torque corresponding to a passive torque to the shaft 350 and the brake 390 may be supported to the second support plate 313. The brake 390 may be located above the motor 380. For example, the brake 390 may be a brake facilitating torque control such as a powder brake or a magnetorheological fluid brake.

Referring to FIGS. 1-3, the motor 380 may be located below the brake 390, the motor 380 may be connected to the bottom end of the shaft 350, and the brake 390 may be connected to a middle portion of the shaft 350. Thus, the motor 380 may stably transmit the driving torque corresponding to the active torque to the shaft 350 and the brake 390 may stably transmit the braking torque corresponding to the passive torque to the shaft 350.

As described above, the haptic simulation system 10 for a vehicle door according to an embodiment of the present disclosure may realistically simulate the sense of opening and closing, manipulation, and the like of the simulator door 320 with safety as the motor 380 provides the driving torque corresponding to the active torque to the shaft 350 and as the brake 390 provides the braking torque corresponding to the passive torque to the shaft 350.

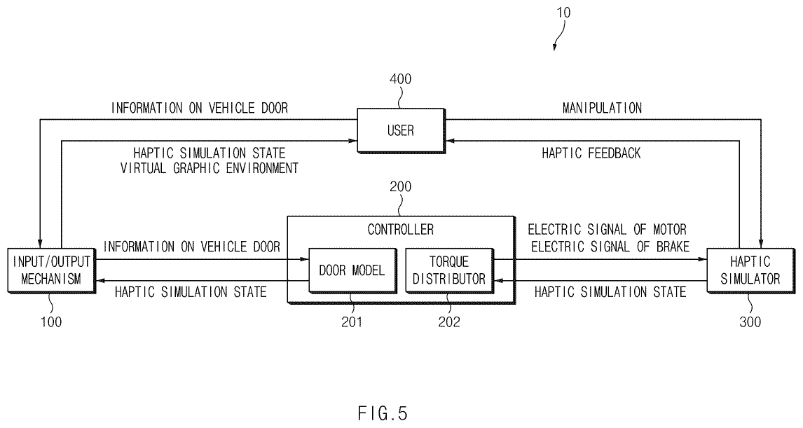

Referring to FIG. 5, a user 400 may input information on a virtual vehicle door to be designed to the input/output mechanism 100. For example, the information on the virtual vehicle door may include the weight of the door, the center of gravity of the door, the torque profile of a checker assembly, the friction of a hinge, and/or the like. The user 400 may manipulate the simulator door 320 of the haptic simulator 300 to move the simulator door 320 in an opening or closing direction. The haptic simulation state of the haptic simulator 300 manipulated by the user 400 may be transmitted to the controller 200. For example, the haptic simulation state may include force/torque that the user 400 applies to the simulator door 320, the angle, angular velocity, and angular acceleration of the simulator door 320 depending on the force/torque applied by the user 400, and the like.

Based on the information received from the input/output mechanism 100 and the haptic simulator 300, the controller 200 may transmit a control signal. The control signal may correspond to the sense of opening and closing of the virtual vehicle door to the motor 380 and the brake 390 of the haptic simulator 300 so that the controller 200 may control the motor 380 and the brake 390 of the haptic simulator 300 in real time. Accordingly, the torque of the shaft 350 and the simulator door 320 may be appropriately controlled so that the user may realistically feel the sense of opening and closing, manipulation, and the like of the virtual vehicle door.

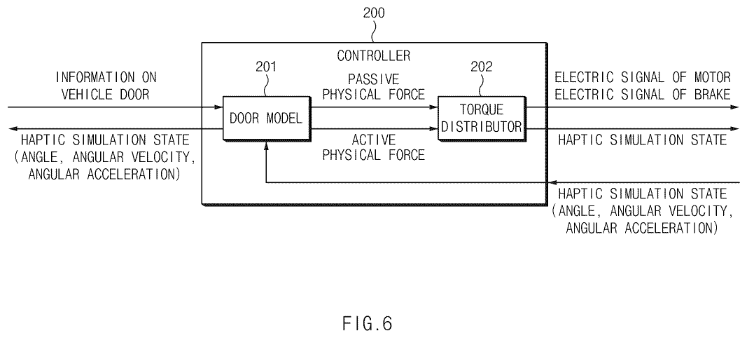

Referring to FIGS. 5 and 6, the controller 200 may include a door model 201 configured to calculate a physical force (force/torque) that the virtual vehicle door applies to the user. The physical force may be calculated based on the information on the virtual vehicle door input to the input/output mechanism 100 and the haptic simulation state of the haptic simulator 300. The controller 200 may also include a torque distributor 202 configured to convert the physical force calculated by the door model 201 into an electric signal (control signal).

Referring to FIG. 6, the door model 201 may calculate the physical force (magnitude of the force/torque) that the virtual vehicle door applies to the user in order to simulate the sense of opening and closing of the virtual vehicle door. The door model 201 may distribute the physical force into a passive physical force (passive torque) and an active physical force (active torque) and may transmit them to the torque distributor 202. The passive physical force refers to a force with a direction that changes depending on the opening and closing of the vehicle door. Thus, the passive physical force may be a passive torque transmitted to the simulator door 320 by the brake 390. The active physical force refers to a force with a direction that does not change depending on the opening and closing of the vehicle door. Thus, the active physical force may be an active torque transmitted to the simulator door 320 by the motor 380.

The torque distributor 202 may transmit the control signal generated based on the information on the virtual vehicle door input to the input/output mechanism and the haptic simulation state of the haptic simulator manipulated by the user to the haptic simulator 300. Referring to FIG. 6, the torque distributor 202 may convert the passive physical force (passive torque) received from the door model 201 into an electric signal of the brake 390. The torque distributor 202 may also convert the active physical force (active torque) received from the door model 201 into an electric signal of the motor 380. The torque distributor 202 may transmit the electric signal of the brake 390 to the brake 390 of the haptic simulator 300 and may transmit the electric signal of the motor 380 to the motor 380 of the haptic simulator 300. Accordingly, the simulator door 320 of the haptic simulator 300 may be controlled by the motor 380 and the brake 390 in real time so that the haptic simulator 300 may provide realistic haptic feedback (tactile sense, kinesthetic sense, etc.) to the user 400. Thus, the user 400 may realistically feel the sense of opening and closing, manipulation, and the like of the virtual vehicle door to be designed.

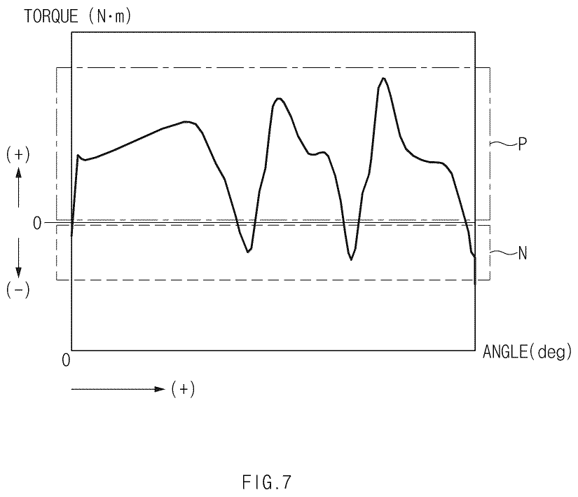

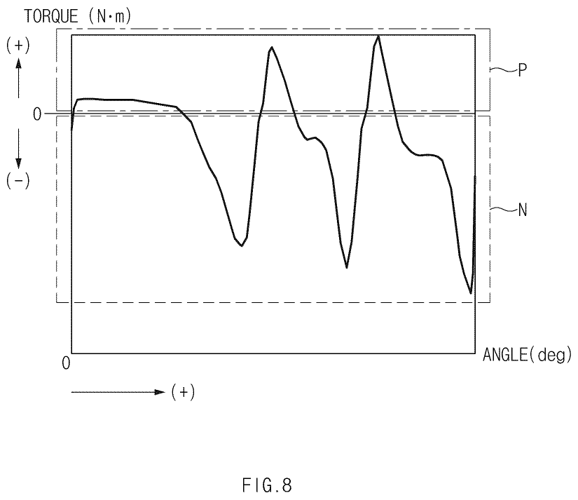

A checker assembly of the vehicle door may serve to ensure that the vehicle door is fixed at a predetermined opening angle. For this reason, as illustrated in FIGS. 7 and 8, the opening torque and closing torque of the vehicle door may differ from each other. Also, the direction of the torque may change while the vehicle door is opened and closed.

FIG. 7 illustrates a graph of the opening torque of the vehicle door generated by the checker assembly of the vehicle door. FIG. 8 illustrates a graph of the closing torque of the vehicle door generated by the checker assembly of the vehicle door. In FIGS. 7 and 8, a positive torque P may be a torque acting in a direction in which the vehicle door is closed and a negative torque N may be a torque acting in a direction in which the vehicle door is opened.

Referring to FIG. 7, when the user opens the vehicle door, the magnitude, direction, and the like of the opening torque may change depending on the rotation angle of the vehicle door. The user may receive a resistance force (force in the direction that is opposite to the direction of force applied by the user) due to the positive torque P. The user may also receive an acceleration force (force in the same direction as the direction of force applied by the user) due to the negative torque N.

Referring to FIG. 8, when the user closes the vehicle door, the magnitude, direction, and the like of the closing torque may change depending on the rotation angle of the vehicle door. The user may receive an acceleration force (force in the same direction as the direction of force applied by the user) due to the positive torque P. The user may also receive a resistance force (force in the direction opposite to the direction of force applied by the user) due to the negative torque N.

Since existing haptic simulators are configured to simulate resistance and acceleration by bidirectional rotation of the motor, it may be necessary to use a type of motor that provides a relatively large force (torque), which may cause injury to the user due to control errors. In addition, since the opening torque and closing torque of the virtual vehicle door to be designed are different from each other, the torque direction of the motor may change drastically when the simulator door of the existing haptic simulator is opened and closed. As the torque direction of the motor changes drastically, the motor may vibrate, causing the user to feel a sense of difference. In other words, since an existing haptic simulator simulates resistance and acceleration using only the motor, it may fail to realistically simulate the sense of opening and closing, manipulation, and the like of the virtual vehicle door to be designed.

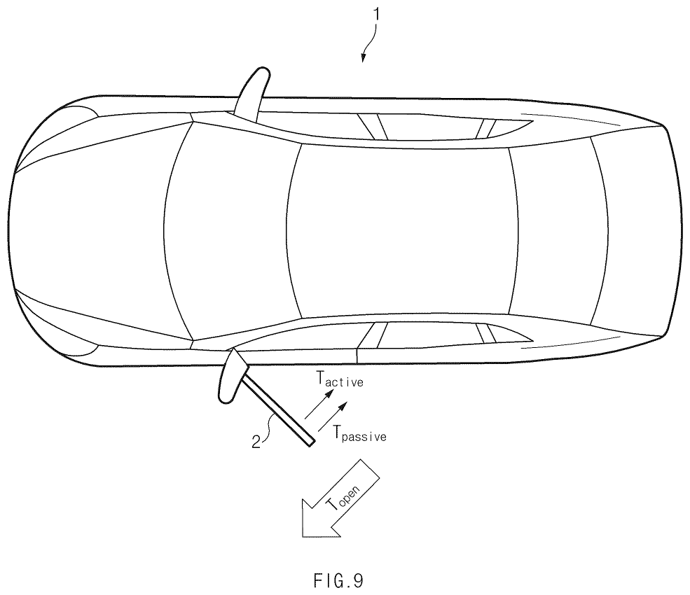

FIG. 9 illustrates an opening torque Tₒₚₑₙ, which a vehicle door 2 applies to a user when the vehicle door 2 of a vehicle 1 is opened. Referring to FIG. 9, the opening torque Tₒₚₑₙ of the vehicle door 2 may be defined as the sum of an active torque T_{active} and a passive torque Tₚₐₛₛᵢᵥₑ as expressed in Equation 1 below.

Tₒₚₑₙ=T_{active}+Tₚₐₛₛᵢᵥₑ Equation 1

The active torque T_{active} refers to a torque with a direction that does not change regardless of the opening and closing of the vehicle door. In FIG. 9, the active torque T_{active} may be a positive torque. The passive torque Tₚₐₛₛᵢᵥₑ refers to a torque with a direction that changes depending on the opening and closing of the vehicle door. In FIG. 9, the passive torque Tₚₐₛₛᵢᵥₑ may be a positive torque.

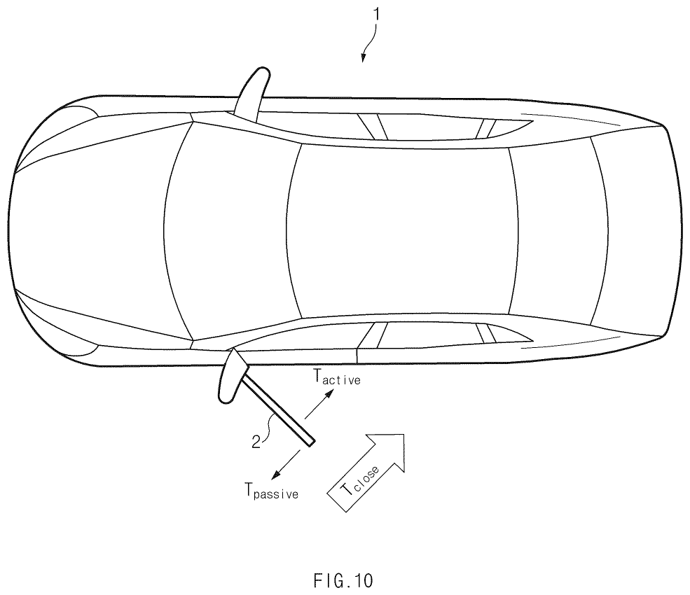

FIG. 10 illustrates a closing torque T_{close}, which the vehicle door 2 applies to the user when the vehicle door 2 of the vehicle 1 is closed. Referring to FIG. 10, the closing torque T_{close} of the vehicle door 2 may be defined as a value obtained by subtracting the passive torque Tₚₐₛₛᵢᵥₑ from the active torque T_{active} as expressed in Equation 2 below.

T_{close}=T_{active}−Tₚₐₛₛᵢᵥₑ Equation 2

The active torque T_{active} refers to a torque with a direction that does not change regardless of the opening and closing of the vehicle door. In FIG. 10, the active torque T_{active} may be a positive torque. The passive torque Tₚₐₛₛᵢᵥₑ refers to a torque with a direction that changes depending on the opening and closing of the vehicle door. In FIG. 10, the passive torque Tₚₐₛₛᵢᵥₑ may be a negative torque.

Based on the above mentioned Equation 1 and Equation 2, the active torque T_{active} and the passive torque Tₚₐₛₛᵢᵥₑ may be calculated as expressed in Equation 3 and Equation 4 below.

T_{active}=(Tₒₚₑₙ+T_{close})/2 Equation 3

Tₚₐₛₛᵢᵥₑ=(Tₒₚₑₙ−T_{close})/2 Equation 4

According to an embodiment of the present disclosure, the motor 380 may be configured to provide the active torque T_{active}, and the brake 390 may be configured to provide the passive torque Tₚₐₛₛᵢᵥₑ. As the motor 380 provides the driving torque corresponding to the active torque, and as the brake 390 provides a braking force (friction) corresponding to the passive torque, the resultant torque acting on the shaft 350 and the simulator door 320 may be controlled in real time.

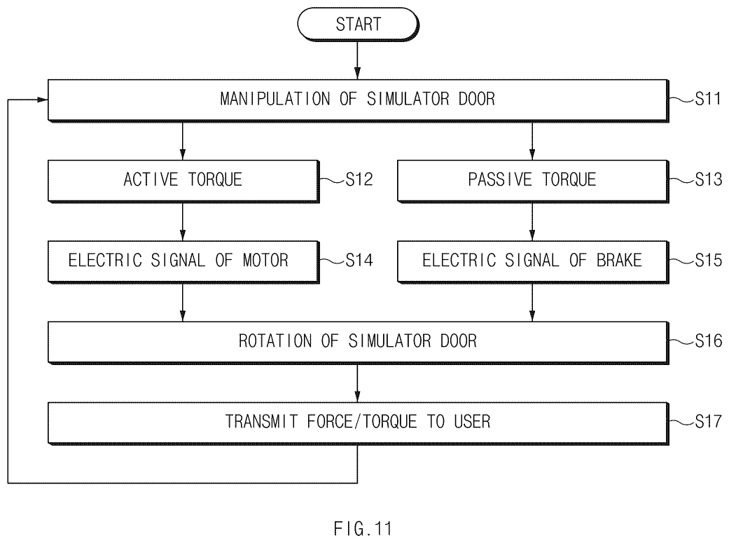

Referring to FIG. 11, when the user manipulates the simulator door 320 (operation S11), the door model 201 of the controller 200 may calculate a physical force (magnitude of force/torque) that the virtual vehicle door applies to the user in order to simulate the sense of opening and closing of the virtual vehicle door. The door model 201 may calculate an active torque based on the above-mentioned physical force (operation S12) and the door model 201 may calculate a passive torque based on the above-mentioned physical force (operation S13).

The torque distributor 202 of the controller 200 may convert the active torque received from the door model 201 into an electric signal of the motor 380 (operation S14). The torque distributor 202 of the controller 200 may convert the passive torque received from the door model 201 into an electric signal of the brake 390 (operation S15).

Accordingly, as the motor 380 and the brake 390 of the haptic simulator 300 are controlled by the controller 200, the simulator door 320 may rotate (operation S16).

As the simulator door 320 rotates, the user may receive the force/torque from the simulator door 320 (operation S17).

As set forth above, the haptic simulation system for a vehicle door according to example embodiments of the present disclosure may include the motor and the brake. The motor may be configured to provide the driving torque corresponding to the active torque to the shaft and the brake may be configured to provide the braking torque corresponding to the passive torque to the shaft. Thus, the haptic simulation system may realistically simulate the sense of opening and closing, manipulation, and the like of the virtual vehicle door to be designed, without having to build a a prototype.

According to example embodiments of the present disclosure, by i) distributing the physical force acting when the vehicle door is opened and closed into the active torque and the passive torque, ii) converting the active torque into the electric signal of the motor, and iii) converting the passive torque into the electric signal of the brake, the haptic simulation system may safely simulate the physical force acting when the vehicle door is opened and closed and may provide more realistic haptic feedback.

The haptic simulation system for a vehicle door according to example embodiments of the present disclosure may provide the realistic haptic feedback (tactile sense, kinesthetic sense, etc.) to the user depending on the simulation state (location, velocity, and acceleration) of the simulator door. Thus, the user may realistically feel the sense of opening and closing, manipulation, and the like of the virtual vehicle door having arbitrary characteristics (mass, characteristics of components, etc.).

The haptic simulation system for a vehicle door according to example embodiments of the present disclosure may realistically simulate the sense of opening and closing, manipulation, and the like of the vehicle door with the use of only design data without creating a prototype in a vehicle door design process. Accordingly, the haptic simulation system may i) adjust vehicle door design variables, ii) search for design data for a vehicle door providing a specific feel by means of the haptic simulator, and iii) apply these design data to an actual vehicle door. Reverse engineering of the vehicle door providing a specific feel is thereby facilitated.

Hereinabove, although the present disclosure has been described with reference to various embodiments and the accompanying drawings, the present disclosure is not limited thereto. The various embodiments may be variously modified and altered by those having ordinary skill in the art to which the present disclosure pertains without departing from the spirit and scope of the present disclosure claimed in the following claims.

What is claimed is:

1. A haptic simulation system for a vehicle door, the haptic simulation system comprising:
a haptic simulator including a simulator frame, a simulator door rotatably connected to the simulator frame through a shaft, a motor configured to rotate the shaft, and a brake configured to brake the shaft,
wherein the motor provides an active torque to the shaft, and
wherein the brake provides a passive torque to the shaft.

2. The haptic simulation system according to claim 1, wherein:
the active torque is a torque in a direction that does not change regardless of the opening and closing of the vehicle door; and
the passive torque is a torque in a direction that changes depending on the opening and closing of the vehicle door.

3. The haptic simulation system according to claim 1, wherein the haptic simulator further includes a torque sensor configured to measure a torque of the shaft.

4. The haptic simulation system according to claim 1, wherein the simulator frame includes at least two stoppers limiting a rotation angle of the simulator door.

5. The haptic simulation system according to claim 1, wherein:
the haptic simulator further includes a connection mechanism configured to connect the simulator door to the shaft; and
the connection mechanism is configured to adjust a height of the simulator door.

6. The haptic simulation system according to claim 1, wherein the haptic simulator further includes a simulator handle mounted on the simulator door.

7. The haptic simulation system according to claim 6, wherein the haptic simulator further includes an adjustment unit configured to adjust a height of the simulator handle with respect to the simulator door.

8. The haptic simulation system according to claim 1, further comprising an input/output mechanism configured to receive information on a virtual vehicle door to be designed and to output a haptic simulation state of the haptic simulator manipulated by a user.

9. The haptic simulation system according to claim 8, further comprising a controller configured to:
transmit a control signal generated based on the information on the virtual vehicle door input to the input/output mechanism and the haptic simulation state of the haptic simulator manipulated by the user to the haptic simulator; and
transmit the haptic simulation state of the haptic simulator to the input/output mechanism.

10. The haptic simulation system according to claim 9, wherein the controller comprises:
a door model configured to calculate a physical force, which the virtual vehicle door applies to the user, based on the information on the virtual vehicle door input to the input/output mechanism and the haptic simulation state of the haptic simulator; and
a torque distributor configured to convert the physical force calculated by the door model into an electric signal.

11. The haptic simulation system according to claim 10, wherein the door model is configured to distribute the physical force into an active torque and a passive torque and to transmit the torques to the torque distributor.

12. The haptic simulation system according to claim 11, wherein the torque distributor is configured to convert the active torque into an electric signal of the motor and to convert the passive torque into an electric signal of the brake.
